(19) United States
(12) Patent Application Publication
(10) Pub. No.: US 2006/0119399 A1
(43) Pub. Date: Jun. 8, 2006

(54) Differential circuits

(76) Inventor: Simon Tam, Cambridge (GB)

Correspondence Address: OLIFF & BERRIDGE, PLC, P.O. BOX 19928, ALEXANDRIA, VA, 22320, US

(21) Appl. No.: 10/538,806

(22) PCT Filed: Aug. 4, 2004
(86) PCT No.: PCT/GB04/03375

§ 371 Date: Jun. 28, 2005

(30) Foreign Application Priority Data
Aug. 4, 2003 (GB) 0318238.3

(51) Int. Cl. H03K 5/22

(52) U.S. Cl. 327/66

(57) ABSTRACT

A single transistor current-mirror is interfaced with a suitable load in combination with a suitable set of switches to accomplish a comparator function. In particular, the differential circuit comprises a single transistor current mirror, including a capacitor connected to the transistor by a switch, and two current sources connected to the current mirror by respective and independent switches, the switch of one of the current sources being operated together with the capacitor switch so as to charge the capacitor and the switch of the other current source being operated so that the circuit operates as a source-follower amplifier with a current-source load. The comparator function is, thus, not influenced by the spatial distribution of the characteristics of the transistors used to implement the circuit.

The present invention relates to differential circuits. Such circuits are used in a wide range of electronic devices including, for example, active matrix display devices.

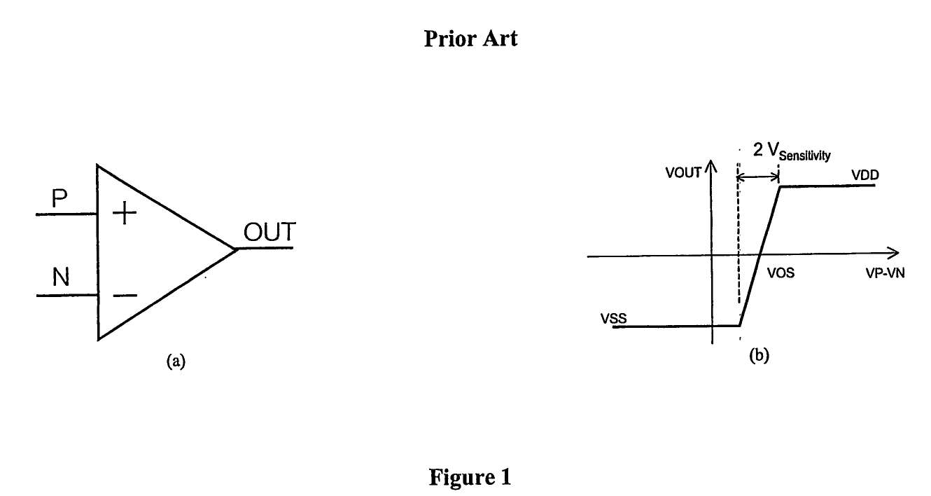

The conventional circuit symbol and graphical definition of a differential voltage comparator are given in FIGS. 1(a) and 1(b) respectively. The output voltage V_{OUT} is related to the two input voltages at nodes P and N (i.e. V_{P} and V_{N}) by:

$$\begin{matrix}\{ \begin{matrix}{V}_{OUT} = {V}_{DD} \\ {V}_{OUT} = {V}_{SS}\end{matrix} & \begin{matrix} if ( {V}_{P} - {V}_{N} - {V}_{OS} ) > {V}_{Sensitivity} \\ if ( {V}_{P} - {V}_{N} - {V}_{OS} ) < {V}_{Sensitivity}\end{matrix} \\ {V}_{SS} < {V}_{OUT} < {V}_{DD} & if \vert {V}_{P} - {V}_{N} - {V}_{OS} \vert < {V}_{Sensitivity}\end{matrix}$$

where V_{DD} and V_{SS} are the voltages of the supply rails, V_{OS} is the input offset-voltage caused by non-ideal transistor characteristics, and V_{Sensitivity} is the minimum difference between input voltages before a full output swing (V_{DD}−V_{SS}) can occur.

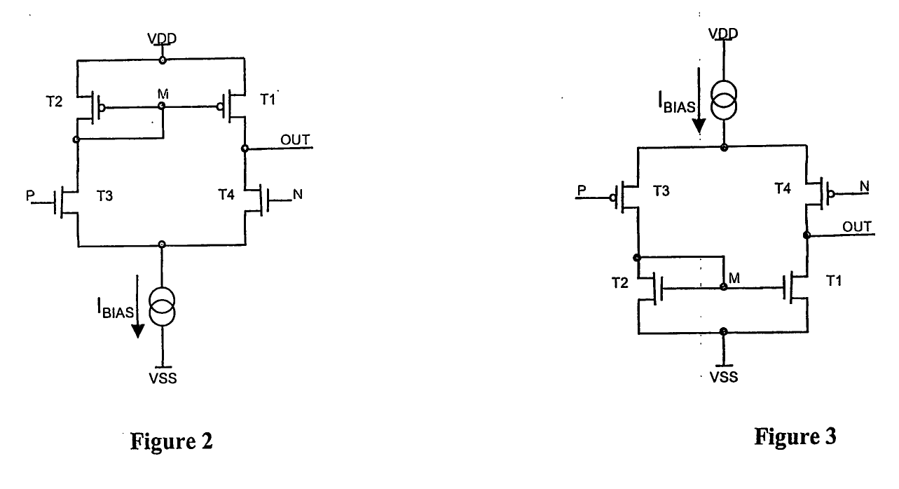

A conventional differential voltage comparator consists of two stages of amplifiers, as is well known in the art. It consists of a differential amplifier circuit as shown in FIGS. 2 and 3 to perform an amplification of the voltage difference between its two inputs V_{P} and V_{N}. For optimum operation, a pair of input transistors T₃ and T₄ identical in characteristics are required to connect to a pair of identical current-mirror transistors T₁ and T₂. In FIG. 2 the inputs are NMOS and in FIG. 3 the inputs are PMOS.

In theory, transistors with the same channel width and length (W and L) dimensions should behave identically. This is normally the case for single crystal technology. However, when the device feature size approaches the sub-micron level, spatial variation of transistor characteristics, although small in absolute terms, becomes a problem. This is because the variation becomes large in relation to the operating voltages. However, when the variation can be described by a linear function of position, this problem can be solved by choosing an appropriate topology for the transistors such that the effect of variation is averaged out. In the case of Thin Film Transistor (TFT) technology, the spatial variation of transistor characteristics is large (in absolute and relative terms) and is randomly distributed. The topological approach cannot be used. An object of the present invention is to solve this problem.

The effect of a random spatial variation of transistor characteristics on a conventional comparator circuit comprising a differential-pair is an unpredictable V_{OS}. One proposed solution is to implement additional switches and a capacitor network for detecting and canceling any input offset-voltage V_{OS} caused by the non-ideal transistor characteristics of the comparator circuit. This is effective, but it increases the component count.

Another solution is not to use a differential-pair. A charge-balance differential-voltage comparator requires only the matching of capacitances. Capacitances are easier to match than transistors.

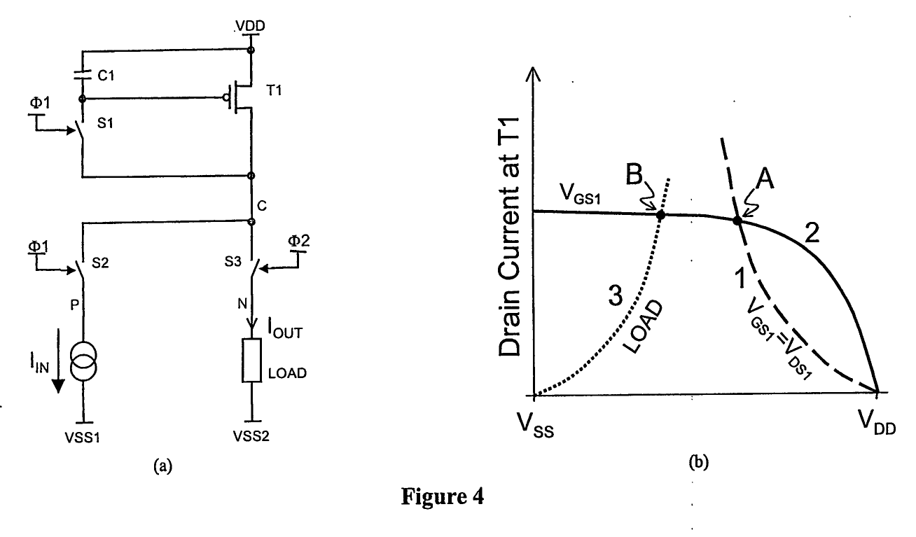

A solution to solve the current-mirror pair problem is to use a single-transistor current-mirror as shown in FIG. 4a. This circuit requires two non-overlapping clock pulses Φ₁ and Φ₂ to operate. The input current I_{IN} sets the gate bias voltage V_{GS1} for transistor T₁ when the switches S₁ and S₂ are turned on. This bias condition is stored across C₁ and mirrors the I_{IN} as output current I_{OUT} on T₁ when S₃ is turned on. FIG. 4b explains the operation graphically. The current level at point A when Φ₁ is high is similar to the current level at point B when Φ₂ is high (i.e. I_{OUT}≈I_{IN}), thus achieving the current-mirror function. In the illustrated circuit the load is a passive device.

According to the present invention a single transistor current-mirror is interfaced with a suitable load in combination with a suitable set of switches to accomplish a comparator function. The comparator function is, thus, not influenced by the spatial distribution of transistor characteristics.

Embodiments of the present invention will now be described by way of further example only and with reference to the accompanying drawings, in which:—

FIGS. 1(a) and 1(b) show the conventional circuit symbol and graphical definition of a differential voltage comparator, respectively;

FIG. 2 shows the input stage of a conventional comparator circuit using a differential pair with NMOS inputs;

FIG. 3 shows the input stage of a conventional comparator circuit using a differential pair with PMOS inputs;

FIGS. 4(a) and 4(b) respectively show a single transistor current-mirror and a graphical description of the operation of that circuit;

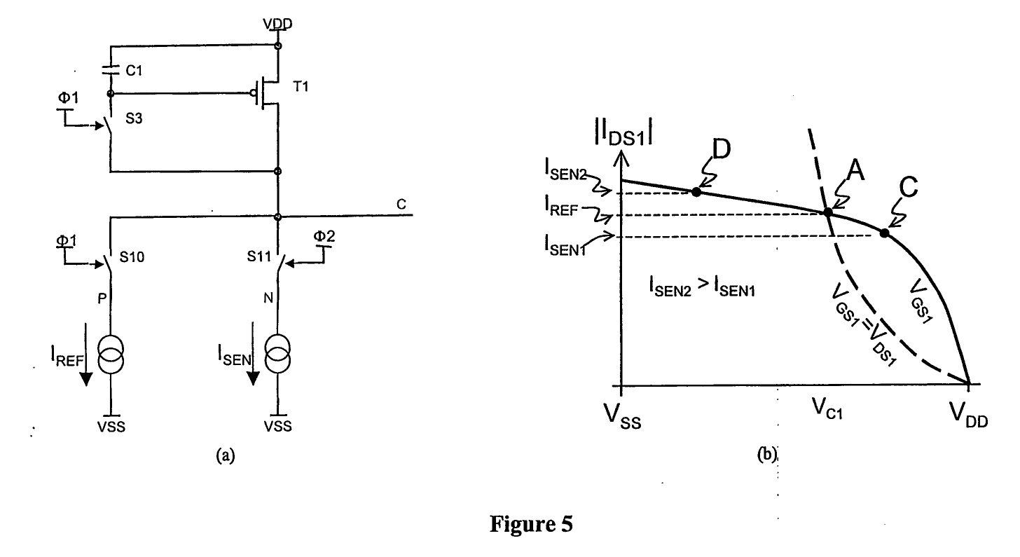

FIGS. 5(a) and 5(b) respectively a circuit according to an embodiment of the present invention and a graphical representation of the operation of that circuit;

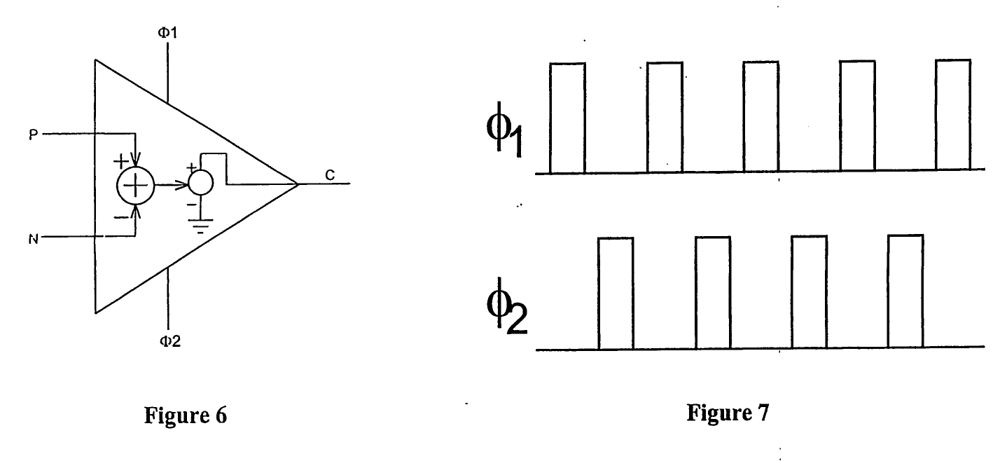

FIG. 6 symbolically illustrates the internal mechanism of a differential comparator according to an embodiment of the present invention;

FIG. 7 shows the driving waveform of the circuit of FIG. 6;

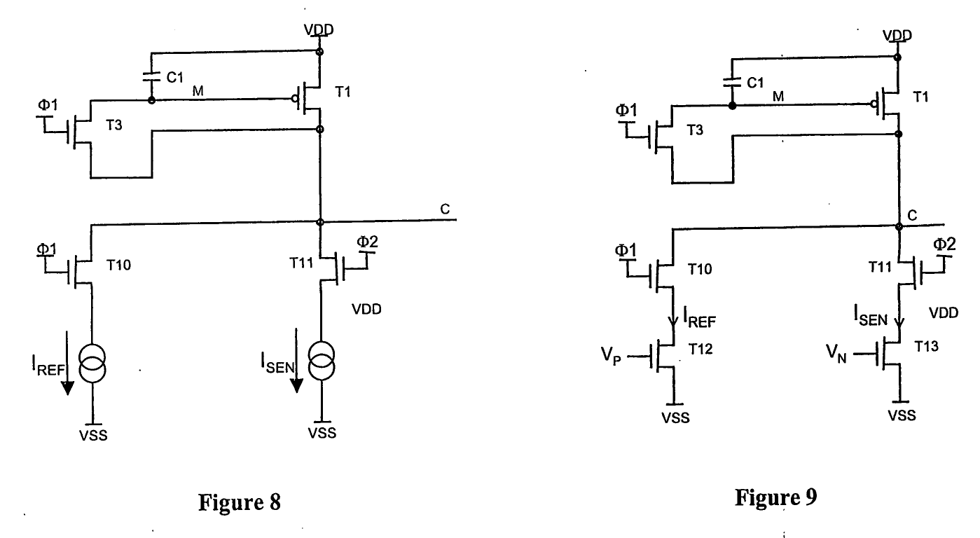

FIG. 8 illustrates a circuit according to an embodiment of the present invention;

FIG. 9 illustrates a circuit according to another embodiment of the present invention;

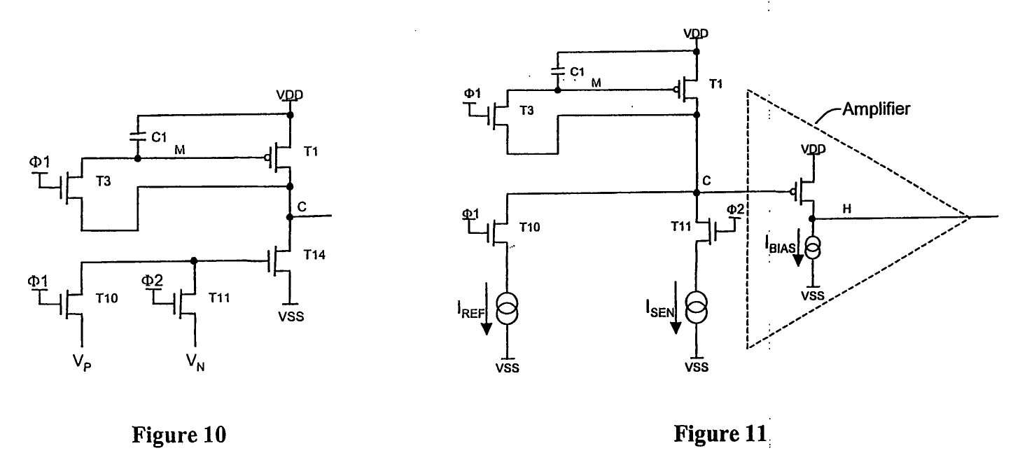

FIG. 10 illustrates a circuit according to a further embodiment of the present invention;

FIG. 11 illustrates the interface of the circuit of one of the embodiments with a following stage in an electronic device;

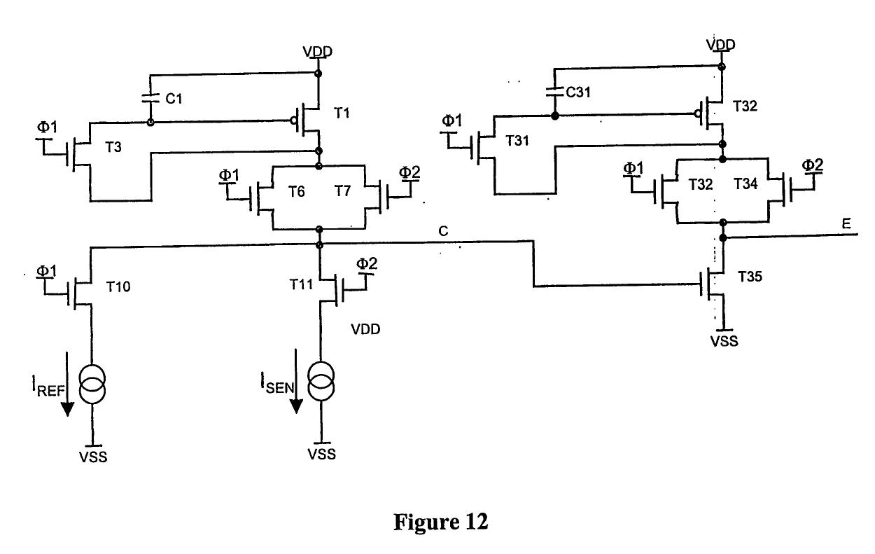

FIG. 12 illustrates another example of the interface of the circuit of one of the embodiments with a following stage in an electronic device;

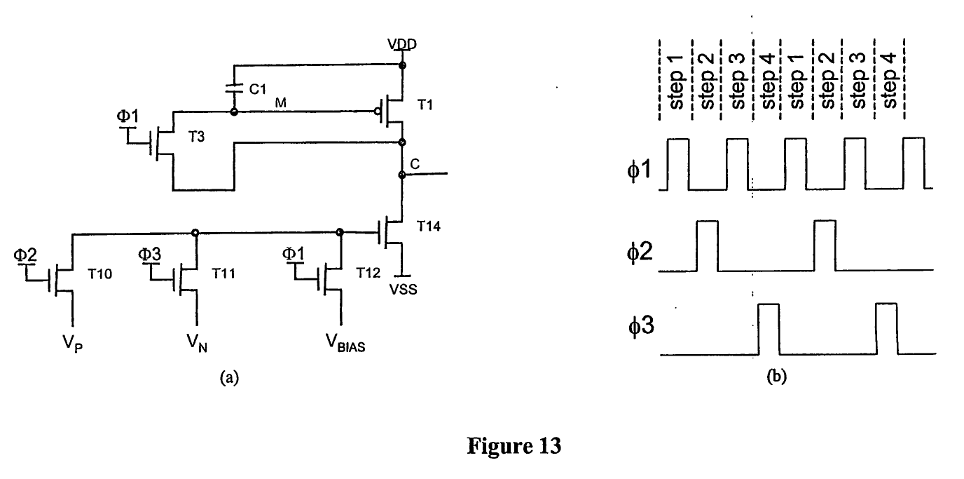

FIG. 13(a) illustrates another embodiment of a circuit according to the present invention and FIG. 13(b) shows the driving waveforms for that circuit;

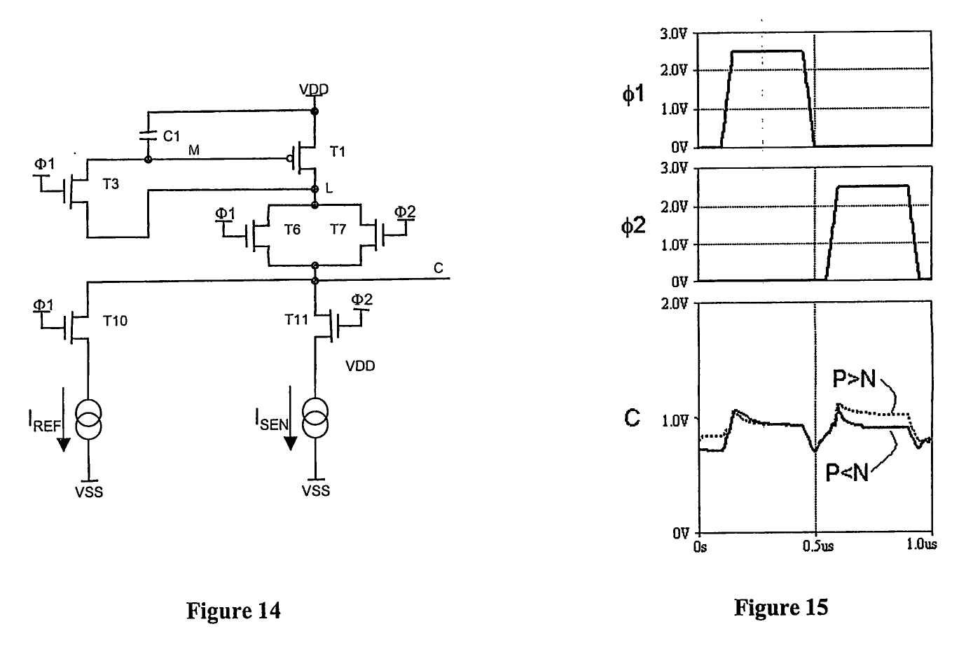

FIG. 14 illustrates a modified form of the circuit of FIG. 8;

FIG. 15 shows simulation results for the circuit of FIG. 9;

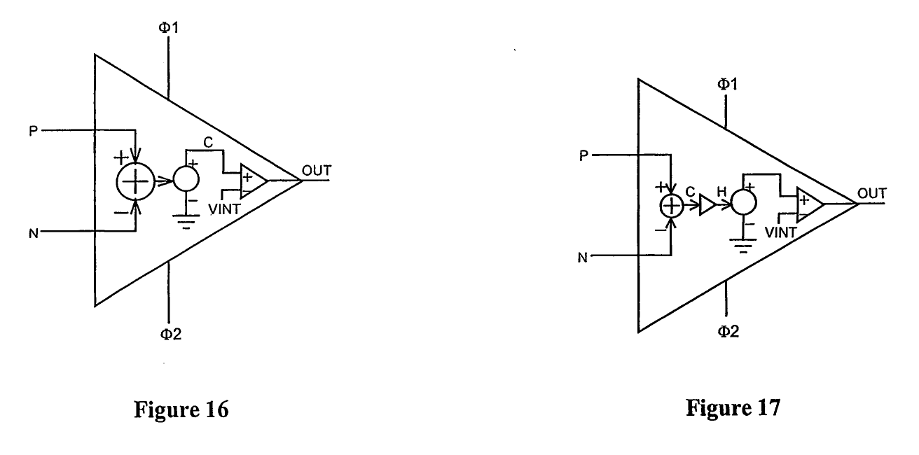

FIG. 16 is a symbolic representation of a differential comparator according to the present invention including an output stage;

FIG. 17 is a variation of FIG. 16;

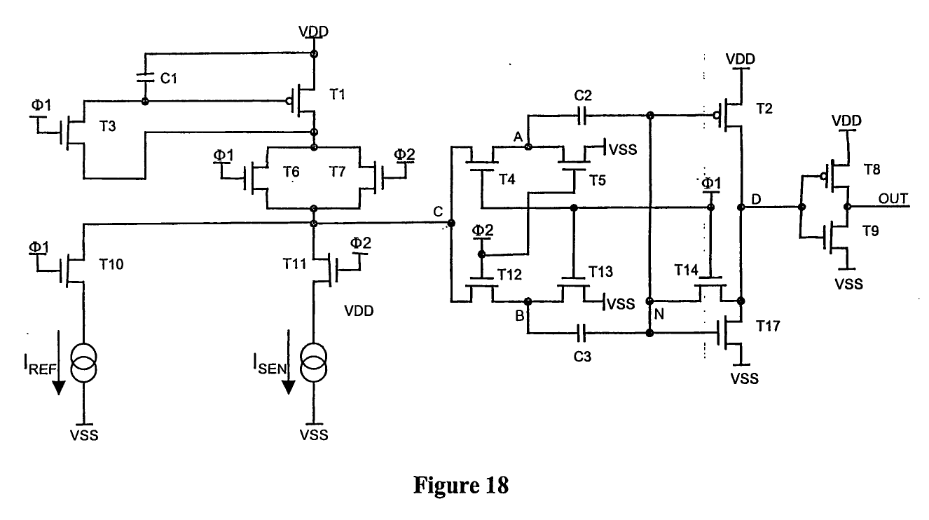

FIG. 18 is a detailed diagram of a circuit in accordance with the present invention;

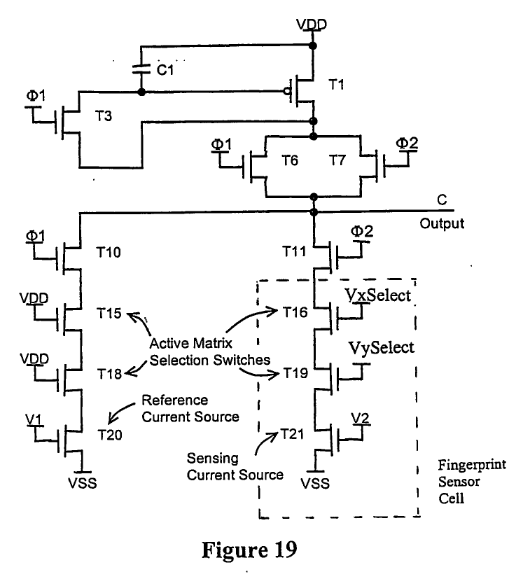

FIG. 19 is a circuit diagram illustrating the input stage of an active matrix sensor cell;

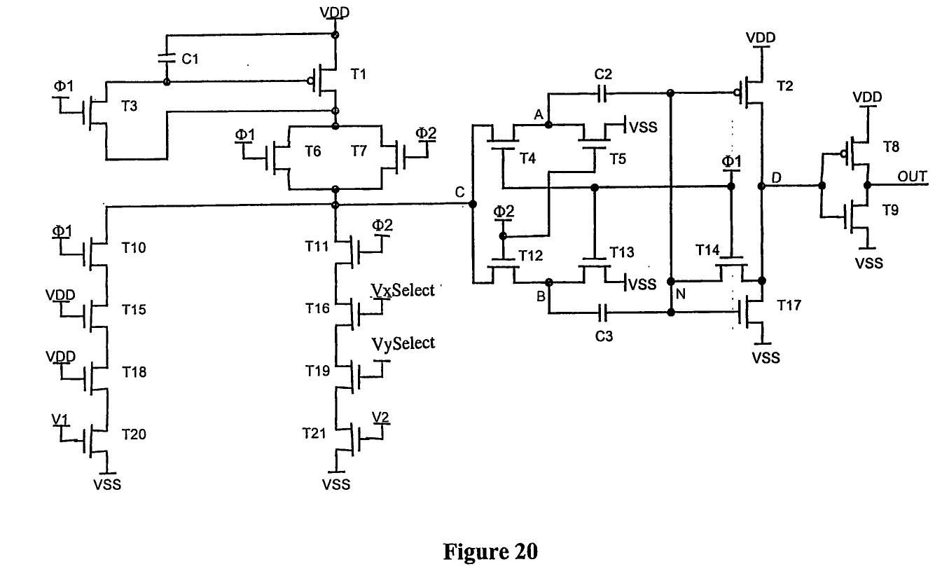

FIG. 20 is a circuit diagram illustrating a current sensor having a discriminator circuit and an output stage;

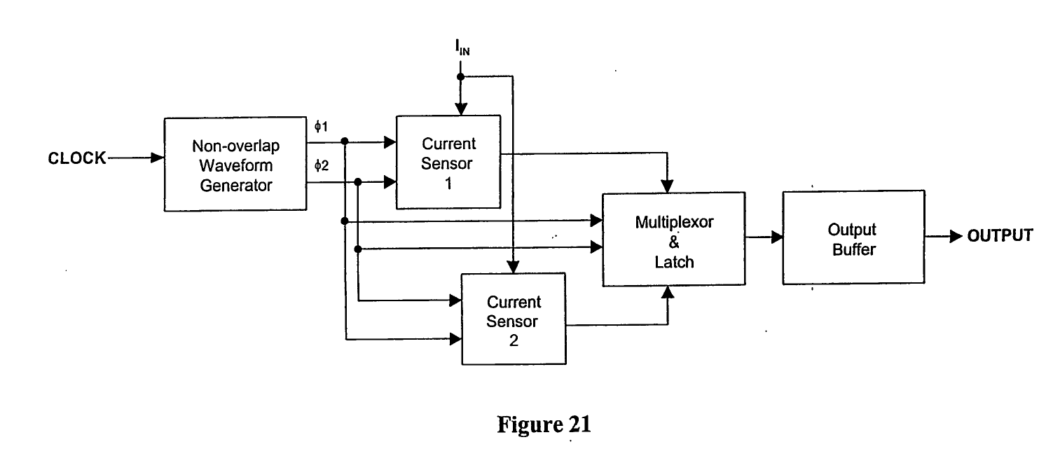

FIG. 21 is a block diagram useful in explaining the driving method of a multiplexed current sensor for use in a finger print sensor; and

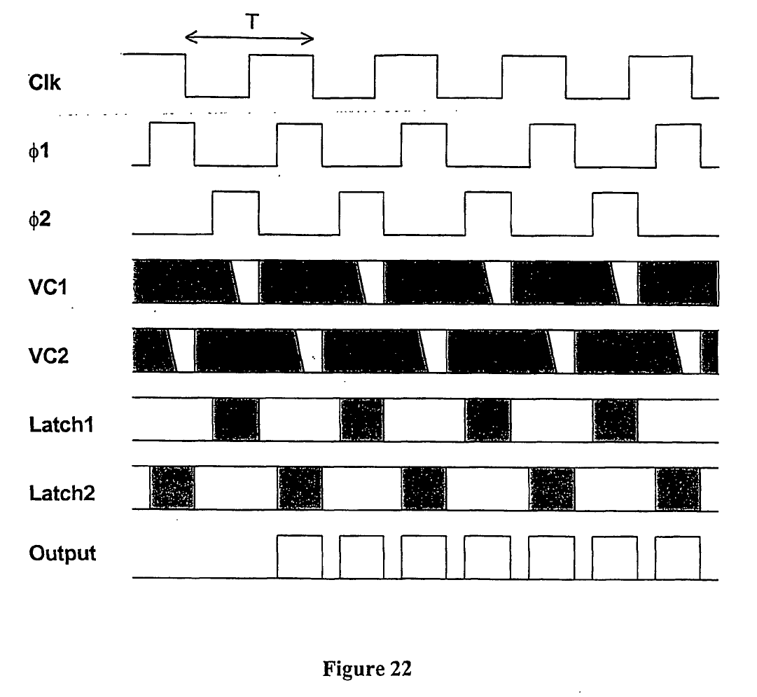

FIG. 22 is a timing diagram of a multiplexed current sensor for use in a finger print sensor.

Embodiments of the present invention will now be described in relation to a differential-current comparator circuit. A method of converting this circuit to a differential-voltage comparator will be described subsequently.

A circuit according to an embodiment of the present invention is illustrated in FIG. 5a. A single-transistor current mirror comprises a transistor T₁ with a capacitor C₁ connected between the source and gate thereof and a switch S₃ connected between the gate and the drain thereof. The switch S3 is operated by a control signal. The single-transistor current-mirror circuit is connected to two current sources that sink I_{REF} and I_{SEN} through switches S₁₀ and S₁₁ driven by two non-overlapping clock signals Φ₁ and Φ₂, respectively. The control signal to the single-transistor current-mirror circuit is connected to Φ₁. The output of this circuit is at node C, and the voltage at this node is referred to as V_{C}.

The operation of this circuit is as follows.

Step 1:

Φ₁ goes high while Φ₂ remains low. Switches S₃ and S₁₀ are now closed. This allows I_{REF} to flow through the diode-connected transistor T₁ and causes a voltage (equal to V_{GS1}, the gate-source voltage of transistor T₁) to appear across the capacitor C₁. The value of C₁ and the on-resistances of switch S₃ dominate the charge-up time. At the end of this cycle, V_{C} settles at a voltage V_{C1}.
   Intermediate Step:
Both Φ₁ and Φ₂ are low. All switches are opened. Both current sources are disconnected from the single-transistor current-mirror circuit. The output voltage V_{C} is floating, or is determined by discharging through the output load (not shown) connected to node C.
   Step 2:
Φ₂ goes high while Φ₁ remains low. Switch S₁₁ is closed. The circuit is now configured as a source-follower amplifier with a current-source load. The output voltage is determined by the current source I_{SEN}. As shown in FIG. 5b, at steady-state, if I_{SEN}=I_{SEN2}, which is greater than I_{REF}, V_{C} will be less than V_{C1}. However, if I_{SEN}=I_{SEN1}, which is less than I_{REF}, V_{C} will be greater than V_{C1}.

FIG. 6 shows a symbol for this differential-current comparator circuit with voltage output. The required driving waveform is given in FIG. 7.

FIG. 8 illustrates a specific example embodiment for the basic schematic as shown in FIG. 5a. The switches S₃, S₁₀ and S₁₁ in FIG. 5a are replaced with n-channel transistors T₃, T₁₀ and T₁₁, respectively. P-channel transistors, in principle, can also be used, but n-channel transistors are preferred because they have a lower on-resistance and hence smaller transistor sizes will be needed. As a result, the voltage feed-through effect of Φ₁ and Φ₂ into nodes C and M is reduced.

The implementation of the current sources depends on the actual applications. One or both of them can be implemented as independent transistors, such as T₁₂ and T₁₃ in Embodiment 2 as shown in FIG. 9, biased to operate in the saturation region. In Embodiment 2, voltages V_{P} and V_{N} controls T₁₂ and T₁₃ to produce I_{REF} and I_{SEN}, respectively. Although the circuit looks like a differential-voltage comparator, care must be taken if it is used as one because the trans-conductance of transistors T₁₂ and T₁₃ may not have the same characteristic (although they are the same size). The circuit as shown in FIG. 10 illustrates how the circuit can be used as a differential-voltage comparator. Transistors T₁₂ and T₁₃ are merged into a single transistor T₁₄, with its gate terminal connected to V_{P} or V_{N} via transistor switches T₁₀ and T₁₁, controlled by Φ₁ and Φ₂, respectively.

The circuits illustrated in FIGS. 5a and 8 to 10 pre-amplify the difference between the input signals and pass the difference signal to the next stage. In order to further increase the output voltage swing and to make sure a minimum output load is attached to node C, a traditional MOS input amplifier (such as a single-ended source-follower amplifier) can be used. This is shown in FIG. 11. Alternatively, node C may be attached to another single-transistor current-mirror circuit for further amplification, as shown in FIG. 12. Essentially, the node C is connected to the gate of a transistor T₃₅ which is connected between VSS and the output of the second single transistor current mirror. In addition, with reference to FIG. 10 and as shown in FIG. 13a, the basic circuit can be expanded by introducing additional transistor switches. In FIG. 13a, transistor T₁₂ is connected between V_{BIAS} and the gate of transistor T₁₄. Additional non-overlapping clock pulses such as that shown in FIG. 13b will also be required. In FIG. 13a; Φ₁ is applied to the gate of T₁₂, Φ₂ is applied to the gate of T₁₀ and Φ₃ is applied to the gate of T₁₁.

The circuits described above in relation to FIGS. 5 to 13 can be modified to improve performance. When Φ1 goes down, the nodal voltage at nodes C and M are pulled down by the voltage feed-through effect at T₃ and T₁₀. Node C suffers the voltage feed-through effect from both T₃ and T₁₀ and hence a greater disturbance results. This disturbance could lead to an unexpected output spike at the second comparator stage. To avoid this problem, additional transistors T₆ and T₇ may be introduced to isolate node C from transistor T₁. The circuit of FIG. 8 modified in this way is illustrated in FIG. 14. Additional transistors T₆ and T₇ are connected in parallel with each other and have their gates each effectively connected with a respective one of the two current source switches (T₁₀ and T₁₁), so as to receive the respective drive signal (Φ₁ and Φ₂) applied to the current source switches.

Simulation results for the circuit as shown in FIG. 9 with this modification added are shown in FIG. 15, with the circuit using polysilicon TFTs. V_{C} falls during the falling edge of Φ₁, but rises by the same amount during the rising edge of Φ₂, therefore the initial operating point of V_{C} during Φ₂ is unaffected.

FIGS. 16 and 17 illustrate schematically how the input stage can be interfaced to a subsequent stage. FIG. 18 is a detailed circuit diagram of the input and self-bias comparator, in accordance with a preferred example of the present invention. The first stage of the circuit is exactly the circuit of FIG. 14. The output node C is connected to the input of a self bias comparator, the body of which comprises transistors T₂, T₄, T₅, T₁₂, T₁₃, T₁₄ and T₁₇ together with capacitors C₂ and C₃. The output stage of the self bias comparator comprises transistors T₈ and T₉. Node C is connected to the source of both of transistors T₄ and T₁₂. The drains thereof are respectively coupled through capacitors C2 and C3 to the respective gates of T₂ and T₁₇. The drains of T₄ and T₁₂ are also respectively connected to the source of T₅ and T₁₃. The drain of both T₅ and T₁₃ are both connected to VSS. Control signal Φ₁ is applied to the gates of T₄ and T₁₃. Control signal Φ₂ is applied to the gates of T₅ and T₁₂. The gates of T₂ and T₁₇ are connected to each other and to the source of a transistor T₁₄, whose drain is connected to the source of T₁₇ and whose gate receives signal Φ₁. The source of T₂ is connected to VDD and it's drain is connected to the source of T₁₇. The drain of T₁₇ is connected to VSS. The interconnection of the drain of T₂ and the source of T₁₇ provides the output to the gates of both T₈ and T₉. The source of T₈ is connected to VDD. The drain of T₉ is connected to VSS and the interconnection between the drain of T₈ and the source of T₉ provides the final circuit output.

This invention can be used in detecting the peak and valley in a fingerprint sensor. An example of a fingerprint sensor circuit is shown in FIG. 19. The current source for I_{SEN} is the output signal from a sensor pixel of an active matrix sensor array. Thus, comparing FIG. 19 with FIG. 14 it will be seen that the reference current source is provided by transistor T₂₀, whose gate receives a voltage V₁, and that the sensing current source is provided by transistor T₂₁, whose gate receives a voltage V₂. Respectively between T₂₀ and T₁₀ and between T₂₁ and T₁₁ are active matrix selection switches T₁₅ and T₁₈, and, T₁₆ and T₁₉. When the sensing cell is selected the voltage VDD is applied to the gates of all of transistors T₁₅, T₁₈, T₁₆ and T₁₉.

FIG. 20 shows an embodiment of a current sensor circuit having a self-bias charge-balance comparator as the output stage. The input stage is the circuit of FIG. 19 and the same self bias comparator as shown in FIG. 18 forms the output stage. The driving scheme is shown in FIG. 21. A non-overlap waveform generator outputs Φ₁ and Φ₂ which are applied as inputs to a first and second current sensor as well as to a multiplexor and latch circuit. The two current sensors receive an input current Iᵢₙ and have their respective outputs connected to the multiplexor and latch circuit. The output of the multiplexor and latch circuit is fed through an output buffer stage so as to provide the final circuit output. The timing diagram for the circuit explained in FIGS. 20 and 21 is shown in FIG. 22.

The aforegoing description has been given by way of example only and it will be appreciated by a person skilled in the art that modifications can be made without departing from the scope of the present invention. For example, in FIG. 20 if the P type transistors are replaced by N type transistors and visa versa then V_{DD} becomes Vss and Vss becomes V_{DD}.

1. A differential circuit comprising a single transistor current mirror, including a capacitor connected to the transistor by a switch, and two current sources connected to the current mirror by respective and independent switches, the switch of one of the current sources being operated together with the capacitor switch so as to charge the capacitor and the switch of the other current source being operated so that the circuit operates as a source-follower amplifier with a current-source load.

2. A differential circuit as claimed in claim 1 wherein the said switches are each implemented as an n-channel transistor.

3. A differential circuit as claimed in claim 1, wherein one or more of the current sources is implemented as an independent transistor.

4. A differential circuit as claimed in claim 1, wherein the current sources are implemented by a single transistor with the gate thereof connected via the two said current source switches to respective voltage inputs.

5. A differential circuit as claimed in claim 4, wherein at least one additional switch is connected to the gate of the said current source single transistor, the additional switch being operated by a drive signal which is independent of and non-overlapping with drive signals applied to the said current source switches and which operably applies an independent voltage to the gate of the said current source single transistor.

6. A differential circuit as claimed in claim 1, wherein the output of the current mirror is connected to a MOS input amplifier.

7. A differential circuit as claimed in claim 1, wherein the output of the current mirror is connected to the input of a second single transistor current mirror.

8. A differential circuit as claimed in claim 1, wherein the said two current source switches are connected to the single transistor current mirror via a transistor pair comprising two transistors connected in parallel with each other and having their gates each effectively connected with a respective one of the said two current source switches, so as to receive the respective drive signal applied to the said two current source switches.

9. A differential circuit as claimed in claim 8, wherein the output of the said single transistor current mirror is connected to a self bias comparator via the said transistor pair.

10. A differential circuit as claimed in claim 1, wherein current source connectable so that the circuit operates as a source-follower amplifier with a current-source load is the output of a sensor pixel of an active matrix sensor array.

11. An electronic device having a differential circuit as claimed in claim 1.
